(19) United States
(12) Patent Application Publication
(10) Pub. No.: US 2026/0229280 A1
(43) Pub. Date: Aug. 6, 2026

(54) MEMORY DEVICE, MEMORY SYSTEM, AND OPERATING METHOD OF INPUT/OUTPUT CIRCUIT

(71) Applicant: Yangtze Memory Technologies Co., Ltd., Wuhan (CN)

(72) Inventors: Mengjie LUO, Wuhan (CN); Chengliang HU, Wuhan (CN); Xiaodong MEI, Wuhan (CN); Huangpeng ZHANG, Wuhan (CN)

(21) Appl. No.: 19/330,921

(22) Filed: Sep. 17, 2025

(30) Foreign Application Priority Data
Feb. 5, 2025 (CN) 202510130765.5

(51) Int. Cl. G11C 11/4096; G11C 11/4093; H03K 19/017

(52) U.S. Cl. CPC G11C 11/4096; G11C 11/4093; H03K 19/01742; G11C 2207/2254

(57) ABSTRACT

Implementations relating to a memory device, a memory system and an operating method of an input/output circuit are disclosed in the present disclosure. In an implementation, a memory device comprises a first die, the first die comprises an impedance calibration circuit; the impedance calibration circuit comprises a receiving circuit, a transmitting circuit, and a calibration control circuit, wherein the receiving circuit is coupled with the calibration control circuit and is configured to generate a calibration start signal; the calibration control circuit is configured to generate a first enable signal based on the calibration start signal, and generate a second enable signal after generating the first enable signal; the transmitting circuit is coupled with the calibration control circuit and is configured to output a third enable signal based on the second enable signal; and the receiving circuit is further configured to generate a first calibration end signal.

### CROSS-REFERENCE TO RELATED APPLICATIONS

This application claims priority to Chinese Patent Application No. 202510130765.5, filed on Feb. 5, 2025, which is hereby incorporated by reference in its entirety.

### TECHNICAL FIELD

The present disclosure relates to the field of semiconductor technologies, and in particular, to a memory device, a memory system, and an operating method of an input/output circuit.

### BACKGROUND

With the continuous development of science and technology today, the semiconductor devices are widely applied in various electronic devices and electronic products. For example, a dynamic random access memory (DRAM), which is a volatile memory device, is a semiconductor memory device commonly used in the computers.

### SUMMARY

The examples of the present disclosure provide a memory device, a memory system, and an operating method of an input/output circuit.

According to a first aspect, an example of the present disclosure provides a memory device, wherein the memory device comprises a first die, the first die comprises an impedance calibration circuit, and the impedance calibration circuit comprises a receiving circuit, a transmitting circuit, and a calibration control circuit, wherein the receiving circuit is coupled with the calibration control circuit and is configured to generate a calibration start signal; the calibration control circuit is configured to generate a first enable signal based on the calibration start signal, and generate a second enable signal after generating the first enable signal; the transmitting circuit is coupled with the calibration control circuit and is configured to output a third enable signal based on the second enable signal; and the receiving circuit is further configured to generate a first calibration end signal.

In an example implementation, the receiving circuit comprises a signal processing circuit, a first signal generating circuit, and a second signal generating circuit; and the transmitting circuit comprises a first output terminal and a second output terminal, wherein an output terminal of the first signal generating circuit and an output terminal of the second signal generating circuit are both coupled with the calibration control circuit; a first input terminal of the first signal generating circuit is coupled with an output terminal of the signal processing circuit; and a first input terminal of the second signal generating circuit is coupled with a first output terminal of the transmitting circuit.

In an example implementation, the transmitting circuit is configured to: generate a second calibration end signal based on the second enable signal, and output the second calibration end signal from the first output terminal of the transmitting circuit; and generate the third enable signal based on the second enable signal, and output the third enable signal from the second output terminal of the transmitting circuit.

In an example implementation, the memory device comprises a plurality of dies, and any one of the plurality of dies comprises the impedance calibration circuit; a die of the plurality of dies that receives a first selecting signal through the receiving circuit of the die is the first die; and a second input terminal of the first signal generating circuit and a second input terminal of the second signal generating circuit of one of the plurality of dies are both coupled with the second output terminal of the transmitting circuit of another one of the plurality of dies.

In an example implementation, the plurality of dies further comprises a plurality of second dies; the plurality of second dies comprises a second die coupled with the transmitting circuit of the first die and a second die coupled with the receiving circuit of the first die; and the receiving circuit of the second die receives a second selecting signal.

In an example implementation, the signal processing circuit of the first die is configured to generate a calibration enable signal based on a calibration command, the first selecting signal, and a first calibration flag signal; and the first signal generating circuit of the first die is configured to generate the calibration start signal of the first die based on the calibration enable signal in response to the first selecting signal.

In an example implementation, the third enable signal comprises a first transition edge and a second transition edge, and the first transition edge is before the second transition edge; the first signal generating circuit of the second die is configured to generate the calibration start signal of the second die based on the first transition edge of the third enable signal received by the receiving circuit of the second die in response to the second selecting signal; and the second signal generating circuit of the first die is configured to generate the first calibration end signal of the first die based on the second transition edge of the third enable signal received by the receiving circuit of the first die in response to the first selecting signal.

In an example implementation, the first signal generating circuit comprises a first selecting circuit and a first signal generator; and the second signal generating circuit comprises a second selecting circuit and a second signal generator, wherein a first input terminal of the first selecting circuit is coupled with the output terminal of the signal processing circuit, and a second input terminal of the first selecting circuit is coupled with the second output terminal of the transmitting circuit of the other die; an input terminal of the first signal generator is coupled with an output terminal of the first selecting circuit, and an output terminal of the first signal generator is coupled with the calibration control circuit; a first input terminal of the second selecting circuit is coupled with a first output terminal of the transmitting circuit, and a second input terminal of the second selecting circuit is coupled with the second output terminal of the transmitting circuit of the other die; and an input terminal of the second signal generator is coupled with an output terminal of the second selecting circuit, and an output terminal of the second signal generator is coupled with the calibration control circuit.

In an example implementation, a control terminal of the first selecting circuit and a control terminal of the second selecting circuit of the first die both receive the first selecting signal, wherein the first selecting signal instructs the first selecting circuit to output a signal received by the first input terminal of the first selecting circuit; and the first selecting signal instructs the second selecting circuit to output a signal received by the second input terminal of the second selecting circuit.

In an example implementation, the calibration command comprises a first calibration command and a second calibration command; the impedance calibration circuit further comprises a third selecting circuit, a first command generating circuit, and a second command generating circuit; an output terminal of the first command generating circuit is coupled with a first input terminal of the third selecting circuit; an output terminal of the second command generating circuit is coupled with a second input terminal of the third selecting circuit; and an output terminal of the third selecting circuit is coupled with an input terminal of the signal processing circuit, wherein the first command generating circuit is configured to periodically generate the first calibration command; the second command generating circuit is configured to receive and parse an external calibration command to generate the second calibration command; and the third selecting circuit is configured to: in a first calibration mode, output the first calibration command; and in a second calibration mode, output the second calibration command.

In an example implementation, the receiving circuit comprises a flip-flop, wherein a first input terminal of the flip-flop receives the calibration start signal; a second input terminal of the flip-flop receives the first calibration end signal; and the flip-flop is configured to output a second calibration flag signal based on the calibration start signal and the first calibration end signal.

In an example implementation, the impedance calibration circuit further comprises a calibration sub-circuit, wherein the calibration sub-circuit is coupled with the calibration control circuit, and is coupled with a reference resistor; and the calibration sub-circuit is configured to: in response to the first enable signal, perform a first calibration operation based on the reference resistor and obtain a first calibration result; and in response to the second enable signal, perform a second calibration operation based on the first calibration result and obtain a second calibration result.

In an example implementation, the memory device further comprises an input/output circuit, wherein the input/output circuit comprises a pull-up driving circuit, a pull-down driving circuit, and the impedance calibration circuit of the first die; and the calibration sub-circuit is further configured to transmit the first calibration result to one of the pull-up driving circuit and the pull-down driving circuit, and transmit the second calibration result to the other of the pull-up driving circuit and the pull-down driving circuit.

According to a second aspect, the present disclosure provides a memory system, comprising: the memory device according to any one of the above implementations; and a controller coupled with at least one of the memory devices and configured to control the memory device.

In an example implementation, the controller is configured to generate an external calibration command; and an input/output circuit in the memory device is configured to perform an impedance calibration operation in response to the external calibration command.

According to a third aspect, the present disclosure provides an operating method of an input/output circuit, comprising: generating a calibration start signal; generating a first enable signal based on the calibration start signal, and generating a second enable signal after generating the first enable signal; outputting a third enable signal based on the second enable signal; and generating a first calibration end signal.

In an example implementation, the operating method further comprises: generating a second calibration end signal based on the second enable signal.

In an example implementation, the generating the calibration start signal comprises: generating a calibration enable signal based on a calibration command, a first selecting signal, and a first calibration flag signal; and in response to the first selecting signal, generating the calibration start signal of the first die based on the calibration enable signal.

In an example implementation, the generating the calibration start signal further comprises: in response to a second selecting signal, generating the calibration start signal of a second die based on a first transition edge of the third enable signal received by a receiving circuit of the second die; and the generating the first calibration end signal comprises: in response to the first selecting signal, generating the first calibration end signal based on a second transition edge of the third enable signal received by a receiving circuit of the first die.

In an example implementation, the calibration command comprises a first calibration command and a second calibration command; and the operating method further comprises: periodically generating the first calibration command; receiving and parsing an external calibration command to generate the second calibration command; in a first calibration mode, outputting the first calibration command; and in a second calibration mode, outputting the second calibration command.

In an example implementation, the operating method further comprises: outputting a second calibration flag signal based on the calibration start signal and the first calibration end signal.

In an example implementation, the operating method further comprises: in response to the first enable signal, performing a first calibration operation based on a reference resistor and obtaining a first calibration result; and in response to the second enable signal, performing a second calibration operation based on the first calibration result and obtaining a second calibration result.

In an example implementation, the operating method further comprises: transmitting the first calibration result to one of a pull-up driving circuit and a pull-down driving circuit, and transmitting the second calibration result to the other of the pull-up driving circuit and the pull-down driving circuit.

### BRIEF DESCRIPTION OF DRAWINGS

FIG. 1 is a schematic diagram of an electronic device according to an example of the present disclosure;

FIG. 2 is a schematic diagram of a DRAM according to an example of the present disclosure;

FIG. 3 is a schematic diagram of a pull-up driving circuit and a pull-down driving circuit according to an example of the present disclosure;

FIG. 4 is a first schematic diagram of an impedance calibration circuit according to an example of the present disclosure;

FIG. 5 is a second schematic diagram of an impedance calibration circuit according to an example of the present disclosure;

FIG. 6 is a schematic diagram of a plurality of dies in a memory device according to an example of the present disclosure;

FIG. 7 is a schematic diagram of connections of a plurality of dies according to an example of the present disclosure;

FIG. 8 is a schematic diagram of a receiving circuit and a transmitting circuit in an impedance calibration circuit according to an example of the present disclosure;

FIG. 9 is a circuit structural diagram of a receiving circuit and a transmitting circuit in an impedance calibration circuit according to an example of the present disclosure;

FIG. 10 is a schematic diagram of a receiving circuit and a transmitting circuit of a first die and a receiving circuit and a transmitting circuit of a second die according to an example of the present disclosure;

FIG. 11 is a timing diagram of performing an impedance calibration operation according to an example of the present disclosure; and

FIG. 12 is a schematic flowchart of an operating method of an input/output circuit according to an example of the present disclosure.

### DETAILED DESCRIPTION

Exemplary implementations disclosed in the present disclosure will be described in more detail below with reference to the accompanying drawings. Although exemplary implementations of the present disclosure are shown in the accompanying drawings, it is to be understood that the present disclosure may be implemented in various forms and should not be limited by the detailed description herein. Rather, these implementations are provided so that the present disclosure can be more thoroughly understood and the scope disclosed in the present disclosure can be fully conveyed to those skilled in the art.

In the following description, numerous details are set forth in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of an actual example are described herein, and well-known functions and structures are not described in detail.

In the drawings, like reference numbers refer to like elements throughout.

It should be understood that spatial relation terms herein such as “beneath”, “below”, “lower”, “under”, “above”, “over”, “upper,” etc., may be for ease of description to describe the relationship between one element or feature and other elements or features shown in the figures. It should be appreciated that in addition to the orientations shown in the figures, the spatial relation term is intended to also encompass different orientations of a device in use and operation. For example, if a device in the figure is flipped, then the device described as “below/under/beneath” the other element or feature will be oriented “above/over/on” the other element or feature. Thus, the exemplary terms “below” and “under” may comprise both upper and lower orientations. The device may be otherwise oriented (rotated 90 degrees or at other orientations) and the spatial description descriptors used herein may likewise be interpreted accordingly.

A term used herein is for the purpose of describing a particular example only and is not to be considered as limitation of the present disclosure. As used herein, the singular forms “a”, “an”, and “said/the” are intended to comprise the plural forms as well, unless the context clearly dictates otherwise. It should also be understood that the terms “consists of” and/or “comprising”, when used in this description, identify the presence of stated features, integers, steps, operations, elements and/or parts, but do not exclude the presence or addition of one or more other features, integers, steps, operations, elements, components and/or combination thereof. As used herein, the term “and/or” comprises any and all combinations of the associated listed items.

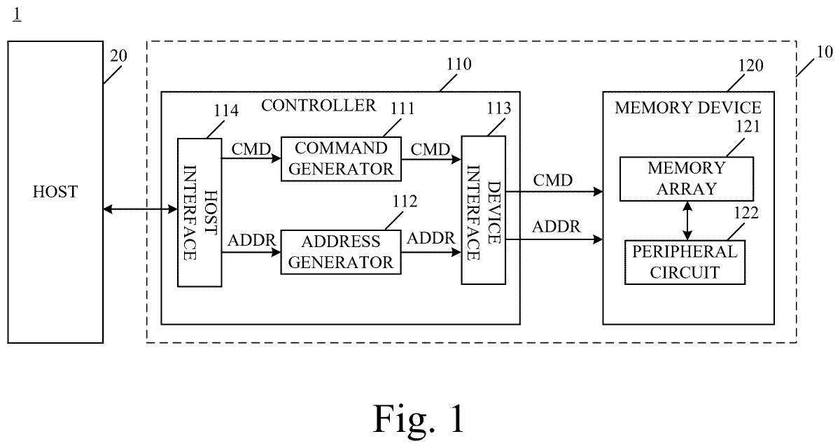

FIG. 1 is a schematic diagram of an electronic device according to an example of the present disclosure. The electronic device 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a storage therein.

As shown in FIG. 1, the electronic device 1 may comprise a memory system 10 and a host 20, and the memory system 10 may comprise a controller 110 and a memory device 120. The host 20 may comprise a processor of the electronic device 1, such as a central processing unit (CPU), or a system on chip (SoC), such as an application processor (AP). The controller 110 is coupled with both the host 20 and the memory device 120, and the controller 110 may be configured to communicate with the host 20 and control the memory device 120.

In some examples, the controller 110 may be configured to control operations of the memory device 120, such as read operations, erase operations, write operations, refresh operations, and the like. In some implementations, the controller 110 is further configured to process Error Correction Code (ECC) with respect to data read from or written to the memory device 120. In other implementations, the controller 110 may be further configured to perform any other suitable operations, such as formatting the memory device 120.

In some examples, the controller 110 may receive data, commands, and addresses from the host 20 and may transmit data, commands, and addresses to the memory device 120. In an example, the controller 110 may comprise a command generator 111, an address generator 112, a device interface 113, and a host interface 114. The controller 110 may receive data, commands, and addresses from the host 20 through the host interface 114, decode commands received from the host 20 by means of the command generator 111 to generate an access command CMD, and may provide the access command CMD to the memory device 120 through the device interface 113. The controller 110 may decode the address received from the host interface 114 by means of the address generator 112 to generate an address ADDR to be accessed in a memory array 121, and may provide the address ADDR to be accessed to the memory device 120 through the device interface 113. The access command may be a signal instructing the memory device 120 to write or read data by accessing one or more memory cells in the memory array 121 corresponding to the address ADDR. In addition, the controller 110 may further transmit a refresh command to the memory device 120, and the refresh command may be a signal instructing the memory device 120 to read and re-write data by accessing one or more memory cells in the memory array 121 corresponding to the address ADDR.

In some examples, the memory device 120 may be a flash memory, such as a NAND type memory, or a random access memory (RAM), such as a dynamic random access memory (DRAM), a synchronous dynamic random access memory (SDRAM), a static random access memory (SRAM), a double rate SDRAM (DDR SDRAM), a phase-change random access memory (PRAM), a resistive random access memory (ReRAM), a magnetic random access memory (MRAM), or the like. An example is described below in which the memory device 120 is a DRAM.

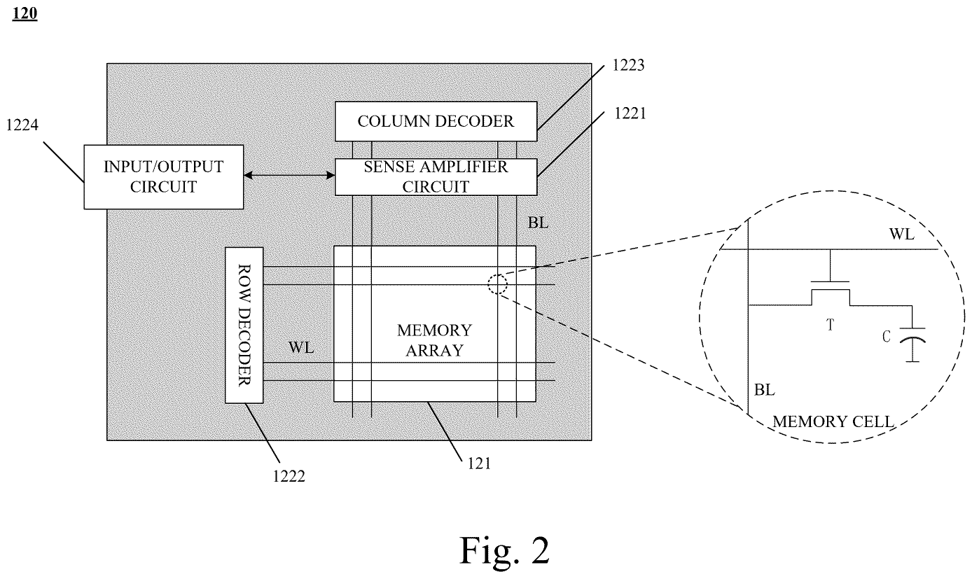

In some examples, FIG. 2 is a schematic diagram of a memory device according to an example of the present disclosure. Referring to FIGS. 1 and 2, the memory device comprises a memory array 121 and a peripheral circuit 122 coupled with the memory array 121, the peripheral circuit 122 may comprise a sense amplifier circuit 1221, a row decoder 1222, a column decoder 1223, an input/output circuit 1224, or the like, the memory array 121 comprises a plurality of memory cells arranged in an array, a plurality of memory cells in a same row are coupled with a word line WL, and a plurality of memory cells in a same column are coupled with a bit line BL. Each memory cell comprises a transistor T and a capacitor C, the word line WL is connected to the gate of the transistor T, the bit line BL is connected to one of the source and the drain of the transistor T, the other of the source and the drain of the transistor T is connected to one electrode of the capacitor C, and the other electrode of the capacitor C is connected to a fixed voltage. The memory cell is configured to store “1” or “0” with the amount of the charges stored in the capacitor C. By specifying the row address and the column address, each memory cell in the DRAM chip can be independently accessed, and the data stored in the memory cell can be read, written or refreshed. Here, FIG. 2 may also be a schematic diagram of one die in a memory device.

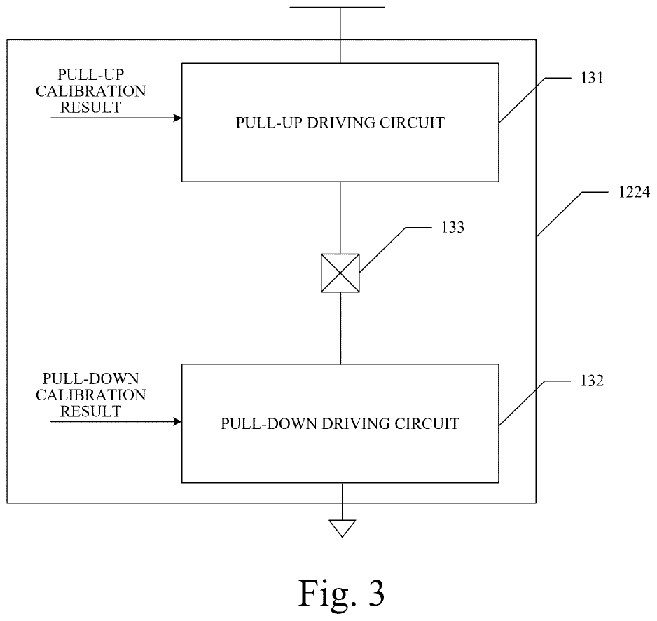

In some examples, referring to FIG. 3, the input/output circuit 1224 may comprise a pull-up driving circuit 131 and a pull-down driving circuit 132. Here, the pull-up driving circuit 131 and the pull-down driving circuit 132 coupled with one input/output pad (for example, the DQ pad) 133 in the input/output circuit 1224 are taken as an example. The pull-up driving circuit 131 may be coupled between the power supply terminal and the input/output pad 133, the pull-down driving circuit 132 may be coupled between the ground terminal and the input/output pad 133, the pull-up driving circuit 131 may comprise a plurality of pull-up drivers, the pull-down driving circuit 132 may comprise a plurality of pull-down drivers, a resistance of each pull-up driver and a resistance of each pull-down driver are a same fixed value, by setting a number of pull-up drivers connected in parallel between the power supply terminal and the input/output pad 133 in the pull-up driving circuit and a number of pull-down drivers connected in parallel between the ground terminal and the input/output pad 133 in the pull-down driving circuit, an input impedance or an output impedance of signal transmission through the input/output pad 133 may be set to match an impedance of the terminal interface and an impedance of the link, thereby reducing signal reflection and improving a signal integrity.

However, due to fluctuations in process and environmental conditions (such as temperature and voltage), it is difficult to remain the resistance of the pull-up driver and the resistance of the pull-down driver constant for a long time, resulting in an impedance matching failure, in which case, the resistance of the pull-up driver and the resistance of the pull-down driver need to be calibrated through impedance calibration (ZQ Calibration).

In some examples, the input/output circuit 1224 may comprise an impedance calibration circuit, which may be coupled with a reference resistor disposed outside the memory device through a ZQ pad, wherein a resistance of the reference resistor is a fixed value and not affected by an environmental condition, and the resistance of the reference resistor is a target resistance of the pull-up driver and the pull-down driver. The impedance calibration circuit may comprise the same pull-up driver as the pull-up driver structure in the pull-up driver circuit and the same pull-down driver as the pull-down driver structure in the pull-down driver circuit, and the impedance calibration process may comprise respectively performing a pull-up calibration and a pull-down calibration based on the reference resistor to respectively adjust the resistance of the pull-up driver and the resistance of the pull-down driver in the impedance calibration circuit to the target resistance, and obtain corresponding calibration results (for example, a calibration code for setting the resistance of the pull-up driver and a calibration code for setting the resistance of the pull-down driver). The pull-up calibration result and the pull-down calibration result may be respectively transmitted to the pull-up driving circuit and the pull-down driving circuit to respectively adjust the resistances of the plurality of pull-up drivers in the pull-up driving circuit and the resistances of the plurality of pull-down drivers in the pull-down driving circuit.

In some examples, the memory device may comprise a plurality of dies, and the impedance calibration circuits of the plurality of dies are coupled with a same reference resistor, so impedance calibrations need to be performed sequentially on the plurality of dies, which consumes a large amount of time, resulting in a relatively low efficiency of impedance calibration, thereby affecting a response speed of the memory device. Therefore, there is a need to improve the efficiency of performing impedance calibration on the memory device comprising the plurality of dies.

In this regard, the present disclosure provides the following implementations.

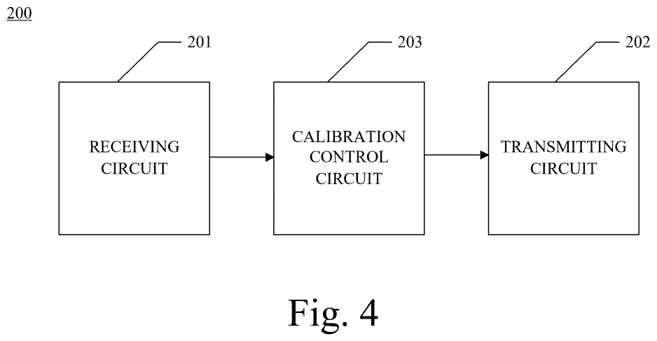

The present disclosure provides a memory device, wherein the memory device comprises a first die, and the first die comprises an impedance calibration circuit. FIG. 4 is a first schematic diagram of an impedance calibration circuit according to an example of the present disclosure. Referring to FIG. 4, the impedance calibration circuit 200 comprises a receiving circuit 201, a transmitting circuit 202, and a calibration control circuit 203, wherein the receiving circuit 201 is coupled with the calibration control circuit 203 and is configured to generate a calibration start signal; the calibration control circuit 203 is configured to generate a first enable signal based on the calibration start signal, and generate a second enable signal after generating the first enable signal; the transmitting circuit 202 is coupled with the calibration control circuit 203 and is configured to output a third enable signal based on the second enable signal; and the receiving circuit 201 is further configured to generate a first calibration end signal.

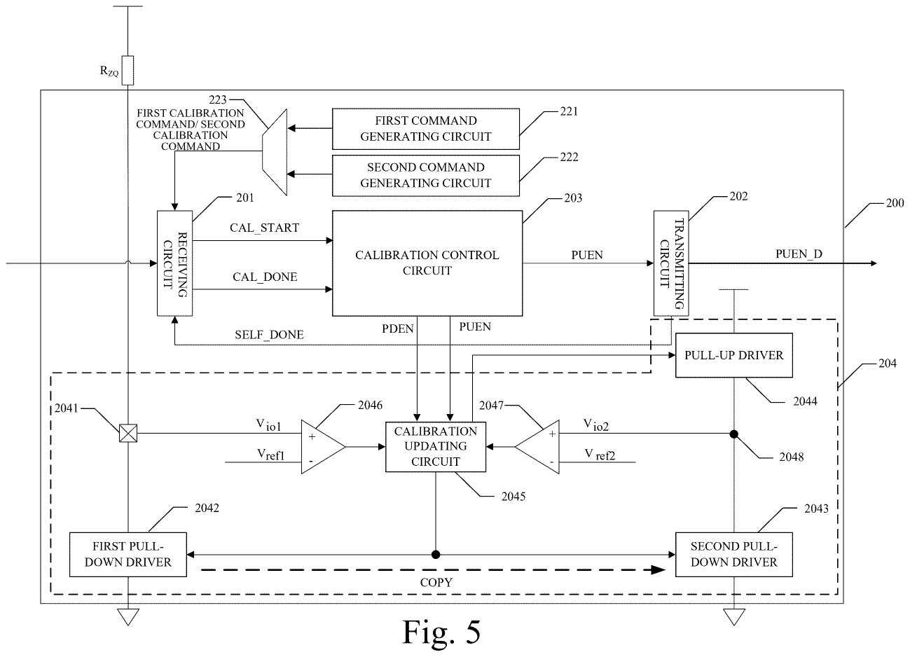

FIG. 5 is a second schematic diagram of an impedance calibration circuit according to an example of the present disclosure. With reference to both FIG. 4 and FIG. 5, the receiving circuit 201 is configured to generate a calibration start signal CAL_START; the calibration control circuit 203 is configured to generate a first enable signal PDEN based on the calibration start signal CAL_START, and generate a second enable signal PUEN after generating the first enable signal PDEN; the transmitting circuit 202 is configured to output a third enable signal PUEN_D based on the second enable signal PUEN; and the receiving circuit 201 is further configured to generate a first calibration end signal CAL_DONE.

In some examples, referring to FIG. 5, the impedance calibration circuit further comprises a calibration sub-circuit 204, wherein the calibration sub-circuit 204 is coupled with the calibration control circuit 203, and the calibration sub-circuit 204 is coupled with the reference resistor R_{ZQ}; and the calibration sub-circuit 204 is configured to: in response to the first enable signal PDEN, perform a first calibration operation based on the reference resistor R_{ZQ} and obtain a first calibration result; and in response to the second enable signal PUEN, perform a second calibration operation based on the first calibration result and obtain a second calibration result.

In some examples, the calibration sub-circuit 204 comprises a ZQ pad 2041, a first pull-down driver 2042, a second pull-down driver 2043, a pull-up driver 2044, a calibration updating circuit 2045, a first comparator 2046, and a second comparator 2047, wherein the ZQ pad 2041 is coupled with an external reference resistor R_{ZQ}, the reference resistor R_{ZQ} is coupled with the power terminal; the first pull-down driver 2042 and the second pull-down driver 2043 have the same circuit structure, and the first pull-down driver 2042 and the second pull-down driver 2043 are both coupled with the ground terminal; and the pull-up driver 2044 is coupled with the power terminal.

In some examples, the process of performing the first calibration operation may comprise: transmitting, by a calibration updating circuit 2045, an initial calibration code of the pull-down driver to the first pull-down driver 2042 in response to the first enable signal PDEN to set the resistance of the first pull-down driver 2042; and comparing, by a first comparator 2046, the voltage Vᵢₒ₁ on the ZQ pad 2041 to the first reference voltage V_{ref1}, and transmitting the comparison result to the calibration updating circuit 2045. Here, taking the voltage of the power supply terminal being V_{DD} as an example, the first reference voltage V_{ref1} may be equal to V_{DD}/2, and if the resistance of the first pull-down driver 2042 is equal to the resistance of the reference resistor R_{ZQ}, then the voltage Vᵢₒ₁ on the ZQ pad 2041 is equal to the first reference voltage V_{ref1}, and the first calibration operation ends; and if the resistance of the first pull-down driver 2042 is not equal to the resistance of the reference resistor R_{ZQ}, then the voltage Vᵢₒ₁ on the ZQ pad 2041 is not equal to the first reference voltage V_{ref1}, the calibration updating circuit 2045 may update the calibration code of the pull-down driver according to the comparison result, and transmit the updated calibration code to the first pull-down driver 2042 until the resistance of the first pull-down driver 2042 is equal to the resistance of the reference resistor R_{ZQ}, that is, the voltage Vᵢₒ₁ on the ZQ pad 2041 is equal to the first reference voltage V_{ref1}, and the first calibration operation ends. In the process of performing the first calibration operation, the calibration updating circuit 2045 further transmits the calibration code of the pull-down driver to the second pull-down driver 2043, and when the first calibration operation ends, the resistance of the second pull-down driver 2043 is the same as the resistance of the first pull-down driver 2042. Here, the calibration code of the pull-down driver obtained at the end of the first calibration operation is the first calibration result.

In some examples, the process of performing the second calibration operation may comprise: transmitting, by the calibration updating circuit 2045, an initial calibration code of the pull-up driver to the pull-up driver 2044 in response to the second enable signal PUEN to set the resistance of the pull-up driver 2044; and comparing, by the second comparator 2047, the voltage Vᵢₒ₂ on the node 2048 to the second reference voltage V_{ref2}, and transmitting the comparison result to the calibration updating circuit 2045. Here, the second reference voltage V_{ref2} may also be equal to V_{DD}/2, and if the resistance of the pull-up driver 2044 is equal to the resistance of the second pull-down driver 2043, then the voltage Vᵢₒ₂ on the node 2048 is equal to the second reference voltage V_{ref2}, and the second calibration operation ends; and if the resistance of the pull-up driver 2044 is not equal to the resistance of the second pull-down driver 2043, then the voltage Vᵢₒ₂ on the node 2048 is not equal to the second reference voltage V_{ref2}, the calibration updating circuit 2045 may update the calibration code of the pull-up driver according to the comparison result and transmit the updated calibration code to the pull-up driver 2044 until the resistance of the pull-up driver 2044 is equal to the resistance of the second pull-down driver 2043, that is, the voltage Vᵢₒ₂ on the node 2048 is equal to the second reference voltage V_{ref2}, and the second calibration operation ends. Here, the calibration code of the pull-up driver obtained at the end of the second calibration operation is the second calibration result.

It should be noted that in the example according to the present disclosure, the first enable signal is the pull-down calibration enable signal (PDEN), the first calibration operation is the pull-down calibration operation, the second enable signal is the pull-up calibration enable signal (PUEN), the second calibration operation is the pull-up calibration operation, and performing the impedance calibration operation comprises first performing the pull-down calibration operation and then performing the pull-up calibration operation, but the present disclosure is not limited thereto. In some other examples, the pull-up calibration operation may be performed first and then the pull-down calibration operation is performed, and in this case, the first enable signal is a pull-up calibration enable signal, the first calibration operation is a pull-up calibration operation, the second enable signal is a pull-down calibration enable signal, the second calibration operation is a pull-down calibration operation, and the calibration sub-circuit comprises two pull-up drivers and one pull-down driver, wherein the first pull-up driver is coupled with the ZQ pad, the reference resistor is coupled between the ZQ pad and the ground terminal, the first pull-up driver and the second pull-up driver are both coupled with the power supply terminal, and the pull-down driver is coupled with the ground terminal. For brevity, in the following examples, the first enable signal is the pull-down calibration enable signal (PDEN) and the second enable signal is the pull-up calibration enable signal (PUEN).

In some examples, the memory device comprises an input/output circuit, the input/output circuit comprises a pull-up driving circuit, a pull-down driving circuit, and an impedance calibration circuit of the first die; and the calibration sub-circuit 204 is further configured to: transmit the first calibration result to one of the pull-up driving circuit and the pull-down driving circuit, and transmit the second calibration result to one of the pull-up driving circuit and the pull-down driving circuit.

In some examples, the first calibration result may be transmitted to the pull-down driving circuit to set the resistances of the plurality of pull-down drivers in the pull-down driving circuit, and the second calibration result is transmitted to the pull-up driving circuit to set the resistances of the plurality of pull-up drivers in the pull-up driving circuit. Here, the circuit structure of the pull-down driver in the pull-down driving circuit is the same as the circuit structure of the first pull-down driver 2042 in the calibration sub-circuit 204, and the circuit structure of the pull-up driver in the pull-up driving circuit is the same as the circuit structure of the pull-up driver 2044 in the calibration sub-circuit 204. Thus, the impedance calibration operation for the first die can be completed.

From the process of the impedance calibration operation according to the above examples, it can be seen that it is required to use the reference resistor R_{ZQ} only when performing the first calibration operation, so when the impedance calibration operation needs to be performed on the plurality of dies in the memory device which share the reference resistance R_{ZQ}, the impedance calibration operation of one die may be partially overlapped with the impedance calibration operation of the other die to improve the efficiency of performing the impedance operation on the plurality of dies, which requires connecting the impedance calibration circuits of the plurality of dies.

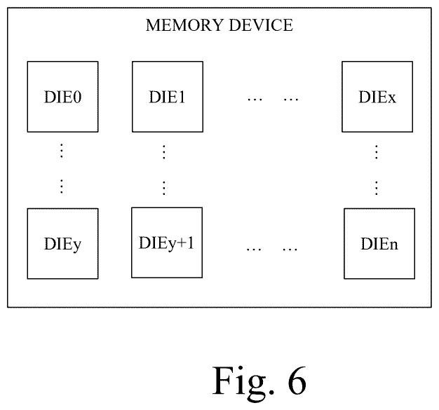

FIG. 6 is a schematic diagram of a plurality of dies in a memory device according to an example of the present disclosure, wherein the memory device may comprise a plurality of dies DIE0 to DIEn, a specific configuration of each die may be similar to that shown in FIG. 2, and each die may comprise a memory array and a sense amplifier, a row decoder, a column decoder, and an input/output circuit coupled with the memory array. Here, the arrangement of the plurality of dies in the memory device and the number of the dies are merely illustrative, and are not intended to limit the memory device according to the examples of the present disclosure.

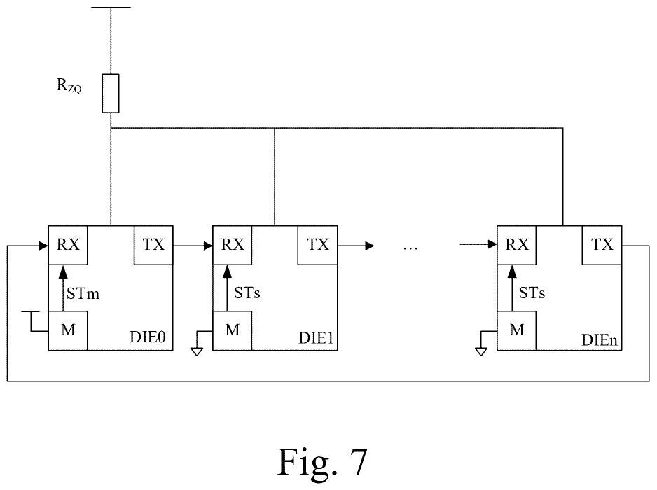

In the examples of the present disclosure, the input/output circuit of any one of the plurality of dies in the memory device may comprise an impedance calibration circuit, and the impedance calibration circuits of the plurality of dies are coupled with a reference resistor R_{ZQ}. In an example, FIG. 7 is a schematic diagram of connections of a plurality of dies according to an example of the present disclosure. With reference to FIGS. 5 to 7, any one of the plurality of dies DIE0 to DIEn may comprise an impedance calibration circuit 200. For two dies coupled with each other in the plurality of dies, a receiving circuit RX of one die is coupled with a transmitting circuit TX of the other die. The plurality of dies may comprise a first die and a plurality of second dies, and here, in an example, the first die is DIE0 and the plurality of second dies are DIE1 to DIEn. The plurality of second dies comprise a second die (DIE1) coupled with the transmitting circuit TX of the first die DIE0 and a second die (DIEn) coupled with the receiving circuit RX of the first die DIE0. In addition, any one of the plurality of dies further comprises a selecting signal generating circuit (M), and the selecting signal generating circuit of the first die DIE0 is connected to the power supply terminal, and is configured to generate a first selecting signal STm, and transmit the first selecting signal STm to the receiving circuit RX of the first die DIE0; and the selecting signal generating circuit of the second die is connected to the ground terminal, and is configured to: generate a second selecting signal STs, and transmit the second selecting signal STs to the receiving circuit RX of the second die. That is, a die in the plurality of dies that receives the first selecting signal STm through the receiving circuit RX of the die is the first die, and all other dies in the plurality of dies that receive the second selecting signal STs through the receiving circuits RX may be the second dies. Here, the first selecting signal STm may be a logic high level, and the second selecting signal STs may be a logic low level.

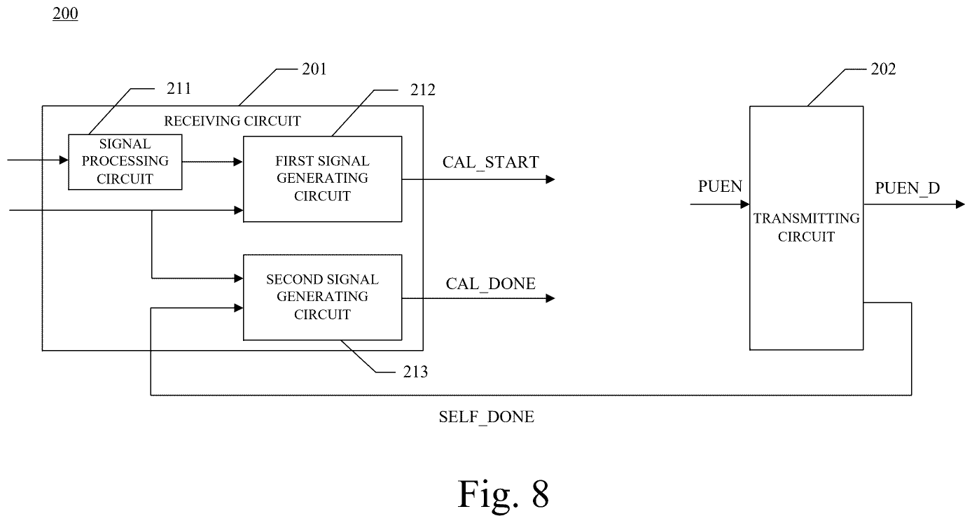

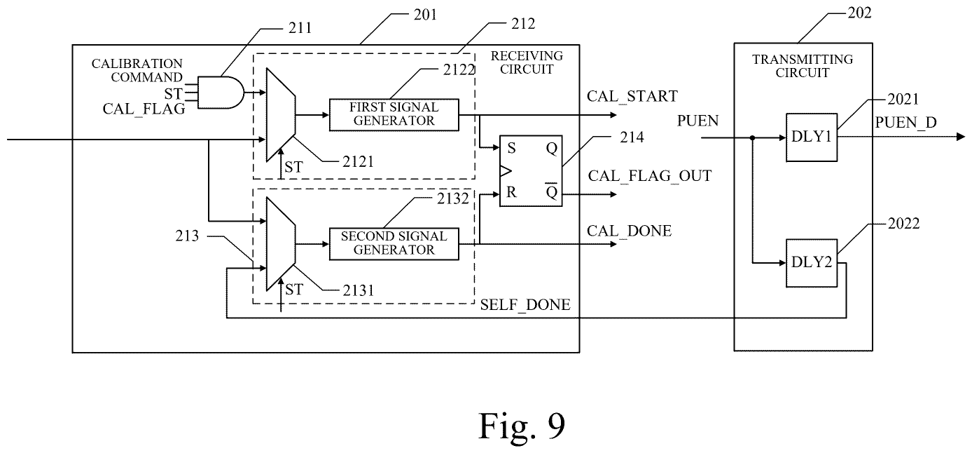

In this example of the present disclosure, the circuit structure of the impedance calibration circuit in the second die may be the same as the circuit structure of the impedance calibration circuit in the first die, and the structure and function of the receiving circuit 201 and the transmitting circuit 202 in the impedance calibration circuit 200 are described below by taking the impedance calibration circuit 200 in one die as an example. FIG. 8 is a schematic diagram of a receiving circuit and a transmitting circuit in an impedance calibration circuit according to an example of the present disclosure, and FIG. 9 is a circuit structural diagram of a receiving circuit and a transmitting circuit in an impedance calibration circuit according to an example of the present disclosure.

In some examples, with reference to FIG. 5, FIG. 7, and FIG. 8, the receiving circuit 201 comprises a signal processing circuit 211, a first signal generating circuit 212, and a second signal generating circuit 213; and the transmitting circuit 202 comprises a first output terminal and a second output terminal, wherein the output terminal of the first signal generating circuit 212 and the output terminal of the second signal generating circuit 213 are both coupled with the calibration control circuit 203; the first input terminal of the first signal generating circuit 212 is coupled with the output terminal of the signal processing circuit 211; the first input terminal of the second signal generating circuit 213 is coupled with the first output terminal of the transmitting circuit 202; and the second input terminal of the first signal generating circuit 212 and the second input terminal of the second signal generating circuit 213 are both coupled with the second output terminal of the transmitting circuit of the other die. Here, the other die may be a die of the plurality of dies that is coupled with the receiving circuit 201 of the die by the transmitting circuit of the die.

In some examples, with reference to FIG. 5, FIG. 7, FIG. 8, and FIG. 9, the signal processing circuit 211 comprises an AND gate, the first signal generating circuit 212 comprises a first selecting circuit 2121 and a first signal generator 2122, and the second signal generating circuit 213 comprises a second selecting circuit 2131 and a second signal generator 2132, wherein the first input terminal of the first selecting circuit 2121 is coupled with the output terminal of the signal processing circuit 2111, and the second input terminal of the first selecting circuit 2121 is coupled with the second output terminal of the transmitting circuit of the other die; the input terminal of the first signal generator 2122 is coupled with the output terminal of the first selecting circuit 2121, and the output terminal of the first signal generator 2122 is coupled with the calibration control circuit 203; the first input terminal of the second selecting circuit 2131 is coupled with the first output terminal of the transmitting circuit 202, and the second input terminal of the second selecting circuit 2131 is coupled with the second output terminal of the transmitting circuit of the other die; and the input terminal of the second signal generator 2132 is coupled with the output terminal of the second selecting circuit 2131, and the output terminal of the second signal generator 2132 is coupled with the calibration control circuit 203.

In an example, the first signal generator 2122 is a rising edge triggered signal generator, and the second signal generator 2132 is a falling edge triggered signal generator. The first signal generator 2122 may generate the calibration start signal CAL_START based on the rising edge of the signal input from its input terminal, and the second signal generator 2132 may generate the first calibration end signal CAL_DONE based on the falling edge of the signal input from its input terminal.

In some examples, the transmitting circuit 202 comprises a first delay circuit 2021 and a second delay circuit 2022, wherein a first output terminal of the transmitting circuit 202 is an output terminal of the second delay circuit 2022, and a second output terminal of the transmitting circuit 202 is an output terminal of the first delay circuit 2021.

In some examples, the transmitting circuit 202 is configured to: generate a second calibration end signal SELF_DONE based on the second enable signal PUEN, and output the second calibration end signal SELF_DONE from the first output terminal of the transmitting circuit 202; generate a third enable signal PUEN_D based on the second enable signal PUEN, and output the third enable signal PUEN_D from the second output terminal of the transmitting circuit 202. Here, the third enable signal PUEN_D and the second calibration end signal SELF_DONE are both signals obtained by delaying the second enable signal PUEN, and a pulse waveform of the third enable signal PUEN_D and a pulse waveform of the second calibration end signal SELF_DONE may both be the same as a pulse waveform of the second enable signal PUEN.

In the example of the present disclosure, with reference to FIG. 7 and FIG. 9, a control terminal of a first selector 2121 and a control terminal of a second selector 2131 receive the same selecting signal ST, and for the first die, the control terminal of the first selector 2121 and the control terminal of the second selector 2131 of the first die receive the first selecting signal STm, and for the second die, the control terminal of the first selector 2121 and the control terminal of the second selector 2131 of the second die receive the second selecting signal STs. Here, the first selecting signal STm instructs the first selecting circuit 2121 to output the signal received by the first input terminal of the first selecting circuit 2121; the first selecting signal STm instructs the second selecting circuit 2131 to output the signal received by the second input terminal of the second selecting circuit 2131; the second selecting signal STs instructs the first selecting circuit 2121 to output the signal received by the second input terminal of the first selecting circuit 2121; and the second selecting signal STs instructs the second selecting circuit 2131 to output the signal received by the first input terminal of the second selecting circuit 2131. The signal generation and transmission process in the impedance calibration process will be described below by taking the first die (DIE0), the second die (DIE1) coupled with the transmitting circuit of the first die, and the second die (DIEn) coupled with the receiving circuit of the first die as an example.

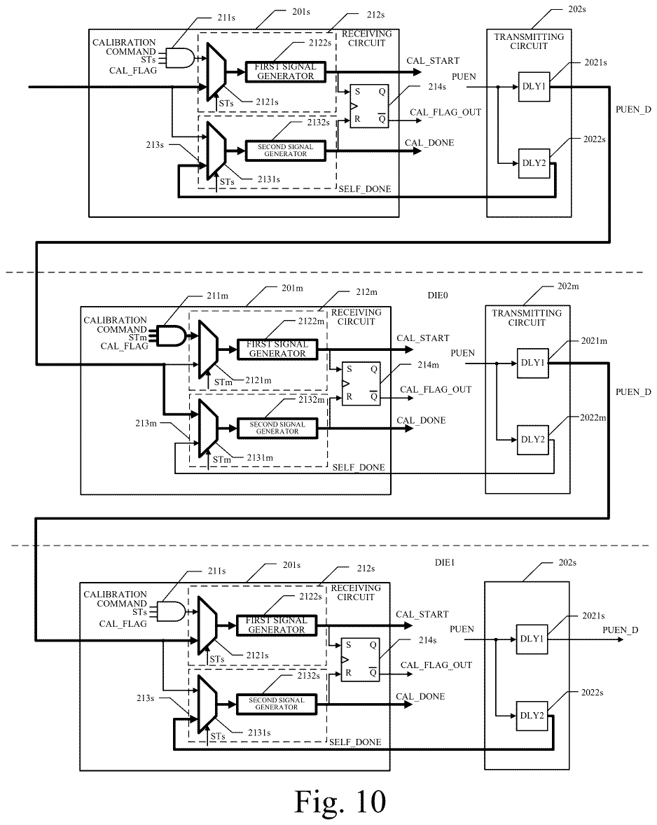

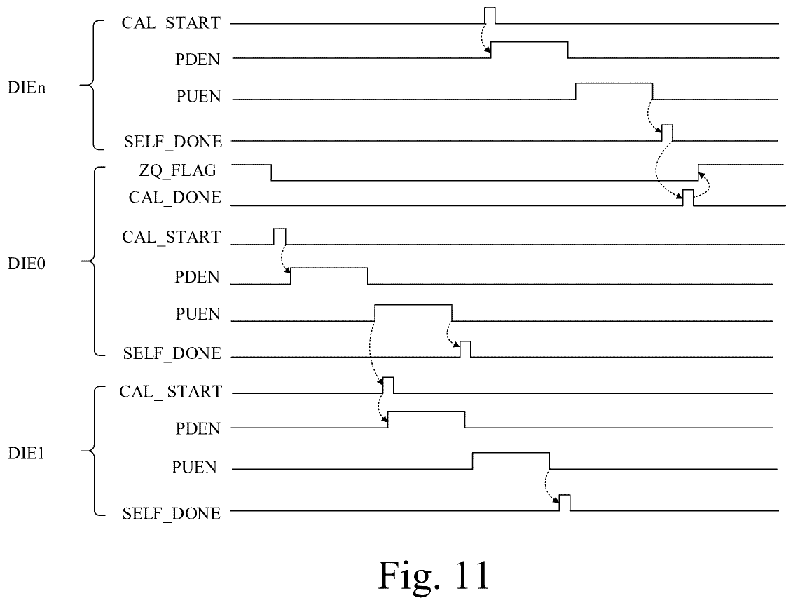

FIG. 10 is a schematic diagram of a receiving circuit and a transmitting circuit of a first die and a receiving circuit and a transmitting circuit of a second die according to an example of the present disclosure, and FIG. 11 is a timing diagram of performing an impedance calibration operation according to an example of the present disclosure. Here, the circuit structure in the first die and the circuit structure in the second die are distinguished by “m” and “s” respectively.

In some examples, referring to FIG. 10, the signal processing circuit 211m of the first die DIE0 is configured to generate a calibration enable signal based on the calibration command, the first selecting signal STm, and the first calibration flag signal CAL_FLAG; and the first signal generating circuit 212m of the first die DIE0 is configured to generate the calibration start signal CAL_START of the first die DIE0 based on the calibration enable signal. In an example, the first selecting circuit 2121m of the first die DIE0 may output a signal received by the first input terminal of the first selecting circuit 2121m in response to the first selecting signal STm; that is, the first selecting circuit 2121m may output the calibration enable signal generated by the signal processing circuit 211m, and output the calibration enable signal to the first signal generator 2122m, wherein the first signal generator 2122m may generate the calibration start signal CAL_START of the first die DIE0 based on the rising edge of the calibration enable signal.

In some examples, with reference to FIG. 5 and FIG. 9, the calibration command may comprise a first calibration command and a second calibration command; the impedance calibration circuit 200 further comprises a third selecting circuit 223, a first command generating circuit 221, and a second command generating circuit 222; an output terminal of the first command generating circuit 221 is coupled with a first input terminal of the third selecting circuit 223; an output terminal of the second command generating circuit 222 is coupled with a second input terminal of the third selecting circuit 223; an output terminal of the third selecting circuit 223 is coupled with an input terminal of the signal processing circuit 211; the first command generating circuit 221 is configured to periodically generate a first calibration command; the second command generating circuit 222 is configured to receive and parse an external calibration command to generate a second calibration command; and the third selecting circuit 223 is configured to: output a first calibration command in a first calibration mode; and output a second calibration command in a second calibration mode. Here, the first calibration mode may be a background calibration mode, and the first command generating circuit 221 may periodically generate the first calibration command, so that the impedance calibration circuit periodically performs the impedance calibration operation. The second calibration mode is a calibration mode in which an impedance calibration operation is performed in response to an external calibration command, which may be generated by a controller; that is, the memory device may perform an impedance calibration operation in response to an external calibration command generated by the controller.

In some examples, with reference to FIG. 10 and FIG. 11, the first calibration flag signal CAL_FLAG may indicate a state of the impedance calibration circuit, and before the impedance calibration operation starts, the first calibration flag signal CAL_FLAG remains at a logic high level, and at this timing, the first selecting signal STm is at the logic high level, therefore if the signal processing circuit 211m of the first die DIE0 receives the calibration command at the logic high level, then the calibration enable signal may be output, and the calibration enable signal is also at the logic high level. Then, the first calibration flag signal CAL_FLAG transitions from the logic high level to a logic low level, indicating that the impedance calibration circuit is in a state in which an impedance calibration operation is being performed, in which case, before this impedance calibration operation is completed, that is, before the first calibration flag signal CAL_FLAG transitions to the logic high level, even if the signal processing circuit 211m of the first die DIE0 receives the calibration command again, no more calibration enable signal will be generated, thereby avoiding interference of the external calibration command on the ongoing impedance calibration operation.

With reference to FIG. 10 and FIG. 11, the calibration control circuit of the first die DIE0 may generate the first enable signal PDEN based on the calibration start signal CAL_START of the first die DIE0, and generate the second enable signal PUEN after generating the first enable signal PDEN to perform the impedance calibration operation on the first die DIE0. The transmitting circuit 202m of the first die DIE0 may generate the third enable signal PUEN_D based on the second enable signal PUEN, and output the third enable signal PUEN_D to the receiving circuit 201s of the second die DIE1.

In some examples, the third enable signal PUEN_D comprises a first transition edge and a second transition edge, and the first transition edge is prior to the second transition edge. Here, the first transition edge being the rising edge and the second transition edge being the falling edge are used as an example. The first signal generating circuit 212s of the second die DIE1 is configured to: in response to the second selecting signal STs, generate the calibration start signal CAL_START of the second die DIE1 based on the first transition edge of the third enable signal PUEN_D received by the receiving circuit 201s of the second die DIE1. In an example, the first selecting circuit 2121s of the second die DIE1 may output the signal received by the second input terminal of the first selecting circuit 2121s in response to the second selecting signal STs, that is, the first selecting circuit 2121s may output the third enable signal PUEN_D received from the first die DIE0, and output the third enable signal PUEN_D to the first signal generator 2122s, and the first signal generator 2122s may generate the calibration start signal CAL_START of the second die DIE1 based on the rising edge of the third enable signal PUEN_D. Then, the calibration control circuit of the second die DIE1 may generate the first enable signal PDEN and the second enable signal PUEN in response to the calibration start signal CAL_START to perform the impedance calibration operation on the second die DIE1. Here, with reference to FIG. 10 and FIG. 11, since the third enable signal PUEN_ D is a signal obtained by delaying the second enable signal PUEN, the calibration start signal CAL_START of the second die may be considered to be generated based on the rising edge of the second enable signal PUEN of the first die DIE0, that is, after the second calibration operation starts to be performed on the first die DIE0 in response to the second enable signal PUEN, the second die DIE1 may generate its calibration enable signal and start to perform the impedance calibration operation.

In the examples of the present disclosure, the calibration start signal of the first die is generated based on the calibration command, the first selecting signal, and the calibration flag signal, that is, the first die may be used as a master die, which is a die in the plurality of dies that first starts to perform the impedance calibration operation. The calibration enable signal of the second die is generated based on a third enable signal output by the previous die, that is, the second die may be used as a slave die, and the first calibration operation of the second die may partially overlap with the second calibration operation of the previous die, thereby improving the efficiency of performing the impedance calibration operation on the plurality of dies.

In some examples, referring to FIG. 9, the transmitting circuit 202 may generate a second calibration end signal SELF_DONE based on the second enabling signal PUEN, and output the second calibration end signal SELF_DONE to the second input terminal of the second signal generating circuit 213 from the first output terminal of the transmitting circuit 202. Referring to FIG. 10, for the second die, the second selecting circuit 2131s in the second signal generating circuit 213s of the second die may output the second calibration end signal SELF_DONE to the second signal generator 2132s in response to the second selecting signal STs, and based on the falling edge of the second calibration end signal SELF_DONE, the second signal generator 2132s may generate the first calibration end signal CAL_DONE of the second die, which is used to indicate the end of the impedance calibration operation on the second die. For the first die, the second selecting circuit 2131m of the second signal generating circuit 213m of the first die will not output the second calibration end signal SELF_DONE to the second signal generator 2132m in response to the first selecting signal STm, and instead will output the third enable signal PUEN_D received from the last second die DIEn to the second signal generator 2132m, and the second signal generator 2132m will generate the first calibration end signal CAL_DONE of the first die DIE0 based on the falling edge of the third enable signal PUEN_D, which is used to indicate the end of the impedance calibration operation on all the dies.

Here, with reference to FIG. 10 and FIG. 11, since the third enable signal PUEN_D is a signal obtained by delaying the second enable signal PUEN, the first calibration end signal CAL_DONE of the first die DIE0 may be considered to be generated based on the falling edge of the second enable signal PUEN of the last second die DIEn. As a result, when the first calibration end signal CAL_DONE of the first die DIE0 is generated, the second calibration operation on the last second die DIEn has been completed, thereby improving the reliability of performing the impedance calibration operation on the plurality of dies.

In some examples, referring back to FIG. 9, the receiving circuit 201 further comprises a flip-flop 214, wherein a first input terminal of the flip-flop 214 receives the calibration start signal CAL_START, and a second input terminal of the flip-flop 214 receives the first calibration end signal CAL_DONE; and the flip-flop 214 is configured to generate a second calibration flag signal CAL_FLAG_OUT based on the calibration start signal CAL_START and the first calibration end signal CAL_DONE. Here, the flip-flop 214 is an SR flip-flop, the first input terminal of the flip-flop 214 may be a set terminal(S), and the second input terminal of the flip-flop 214 may be a reset terminal (R).

With reference to FIG. 10 and FIG. 11, when the second input terminal of the flip-flop 214m of the first die DIE0 receives the first calibration end signal CAL_DONE, if the calibration start signal CAL_START received by the first input terminal of the flip-flop 214m remains at a logic low level, then after the first calibration end signal CAL_DONE received by the second input terminal of the flip-flop 214m transitions to a logic high level, the second calibration flag signal CAL_FLAG_OUT output by the inverting output terminal (Q̅) is set to the logic high level, and after the first calibration end signal CAL_DONE transitions to the low level again, the second calibration flag signal CAL_FLAG_OUT remains at the logic high level. Here, the inverting output terminal of the flip-flop 214m of the first die DIE0 may be coupled to the first calibration flag signal CAL_FLAG, that is, the second calibration flag signal CAL_FLAG_OUT output by the first die DIE0 may set the first calibration flag signal CAL_FLAG from the logic low level to the logic high level, and the rising edge of the first calibration flag signal CAL_FLAG may indicate that the impedance calibration circuits of the plurality of dies have exited the impedance calibration state.

It should be noted that, in the above examples, DIE0 is the first die, and DIE1 to DIEn are the second dies, but the present disclosure is not limited thereto. Since the impedance calibration circuit in the first die and the impedance calibration circuit in the second die have the same circuit structure, the selecting signal generating circuit of any one of DIE0 to DIEn may be connected to the power supply terminal, and the selecting signal generating circuits of the remaining dies are connected to the ground terminal, that is, any die may be used as the mater die, and the remaining dies may be used as the slave dies, for achieving similar effect as the above examples. As such, the flexibility of performing impedance calibration operations on a memory device comprising multiple dies may be improved.

In the example of the present disclosure, the receiving circuit of the first die and the receiving circuit of the second die may receive the first selecting signal and the second selecting signal, respectively, and the signal transmission path of the receiving circuit of the first die may be different from the signal transmission path of the receiving circuit of the second die. On one hand, the receiving circuit of the second die may generate the calibration start signal of the second die based on the first transition edge of the third enable signal output by the previous die, so that the second calibration operation of the second die may partially overlap with the first calibration operation of the previous die, thereby improving the efficiency of performing the impedance calibration operation on the plurality of dies, and increasing the response speed of the memory device; on the other hand, the receiving circuit of the first die may generate the first calibration end signal of the first die based on the second transition edge of the third enable signal output by the last second die, so that when the first calibration end signal of the first die is generated, the second calibration operation of the last second die has been completed. As a result, the first calibration end signal generated by the receiving circuit of the first die can accurately indicate the completion of the impedance calibration operation on the plurality of dies, thereby improving the reliability of performing the impedance calibration operation on the plurality of dies.

Based on a concept similar to that of the above memory device, the present disclosure further provides a memory system, comprising: at least one memory device in any one of the above examples; and a controller coupled with the at least one memory device and configured to control the memory device.

In some examples, the controller is configured to generate an external calibration command; and the input/output circuit in the memory device is configured to perform an impedance calibration operation in response to the external calibration command.

In some examples, referring to FIG. 5, the external calibration command may be received and parsed by the second command generating circuit 222 to generate a second calibration command, and the memory device may perform the impedance calibration operation by the second calibration mode.

Here, for configuration and function of the memory system, a reference to the description of FIG. 1 in the above examples may be made, and details thereof are not described herein again.

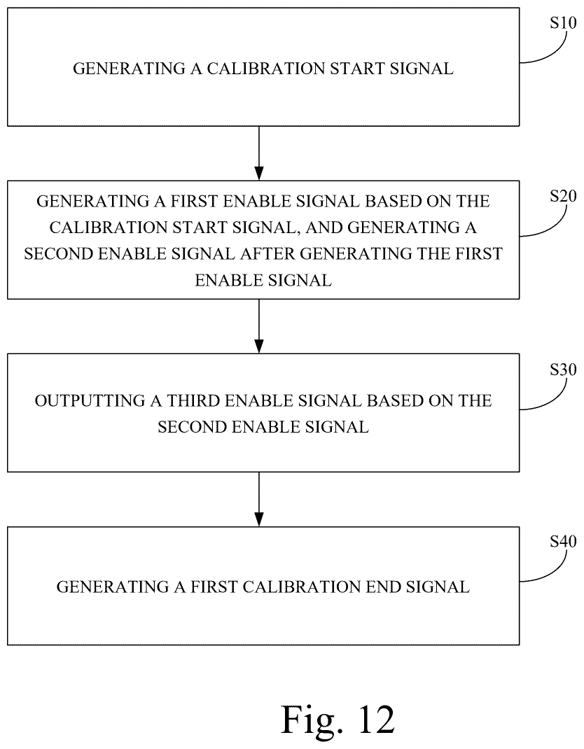

Based on a concept similar to that of the above memory device, the present disclosure further provides an operating method of the input/output circuit. FIG. 12 is a schematic flowchart of an operating method of an input/output circuit according to an example of the present disclosure.

Referring to FIG. 12, the operating method of the input/output circuit comprises: operation S10 of generating a calibration start signal; operation S20 of generating a first enable signal based on the calibration start signal, and generating a second enable signal after generating the first enable signal; operation S30 of outputting a third enable signal based on the second enable signal; and operation S40 of generating a first calibration end signal.

In some examples, the input/output circuit may be an input/output circuit in the memory device according to any one of the above examples, and the input/output circuit may comprise a pull-up driving circuit, a pull-down driving circuit, and an impedance calibration circuit of the plurality of dies.

In some examples, the operating method of the input/output circuit further comprises generating a second calibration end signal based on the second enable signal.

In some examples, performing operation S10 may comprise: generating a calibration enable signal based on a calibration command, a first selecting signal, and a first calibration flag signal; and in response to the first selecting signal, generating the calibration start signal of the first die based on the calibration enable signal.

In some examples, performing operation S10 may further comprise: in response to a second selecting signal, generating the calibration start signal of the second die based on a first transition edge of the third enable signal received by a receiving circuit of a second die; and performing operation S40 may comprise: in response to the first selecting signal, generating the first calibration end signal based on a second transition edge of the third enable signal received by a receiving circuit of the first die.

In some examples, the calibration command comprises a first calibration command and a second calibration command; and the operating method of the input/output circuit further comprises: periodically generating the first calibration command; receiving and parsing an external calibration command to generate the second calibration command; in a first calibration mode, outputting the first calibration command; and in a second calibration mode, outputting the second calibration command.

In some examples, the operating method of the input/output circuit further comprises outputting a second calibration flag signal based on the calibration start signal and the first calibration end signal.

In some examples, the operating method of the input/output circuit further comprises: in response to the first enable signal, performing a first calibration operation based on the reference resistor, and obtaining a first calibration result; and in response to the second enable signal, performing a second calibration operation based on the first calibration result, and obtaining a second calibration result.

In some examples, the operating method of the input/output circuit further comprises transmitting the first calibration result to one of the pull-up driving circuit and the pull-down driving circuit, and transmitting the second calibration result to the other of the pull-up driving circuit and the pull-down driving circuit.

The features disclosed in the several device examples provided by the present disclosure may be arbitrarily combined without conflict to obtain a new device example.

The method disclosed in the several method examples provided by the present disclosure may be arbitrarily combined without conflict to obtain a new method example.

The above descriptions are only specific implementations of the present disclosure, but the protection scope of the present disclosure is not limited thereto. Changes or replacements that may be easily conceived by any person skilled in the art within the technical scope of the present disclosure should be covered within the protection scope of the present disclosure,

What is claimed is:

1. A memory device, comprising:
a first die, comprising:
an impedance calibration circuit, comprising:
a receiving circuit,
a transmitting circuit, and
a calibration control circuit, wherein
the receiving circuit is coupled with the calibration control circuit and is configured to generate a calibration start signal;
the calibration control circuit is configured to generate a first enable signal based on the calibration start signal, and generate a second enable signal after generating the first enable signal;
the transmitting circuit is coupled with the calibration control circuit and is configured to output a third enable signal based on the second enable signal; and
the receiving circuit is further configured to generate a first calibration end signal.

2. The memory device of claim 1, wherein the receiving circuit comprises a signal processing circuit, a first signal generating circuit, and a second signal generating circuit; and the transmitting circuit comprises a first output terminal and a second output terminal, wherein
an output terminal of the first signal generating circuit and an output terminal of the second signal generating circuit are both coupled with the calibration control circuit;
a first input terminal of the first signal generating circuit is coupled with an output terminal of the signal processing circuit; and
a first input terminal of the second signal generating circuit is coupled with a first output terminal of the transmitting circuit.

3. The memory device of claim 2, wherein the transmitting circuit is configured to:
generate a second calibration end signal based on the second enable signal, and output the second calibration end signal from the first output terminal of the transmitting circuit; and
generate the third enable signal based on the second enable signal, and output the third enable signal from the second output terminal of the transmitting circuit.

4. The memory device of claim 2, wherein the memory device comprises a plurality of dies, and any one of the plurality of dies comprises the impedance calibration circuit;
a die of the plurality of dies that receives a first selecting signal through the receiving circuit of the die is the first die; and
a second input terminal of the first signal generating circuit and a second input terminal of the second signal generating circuit of one of the plurality of dies are both coupled with the second output terminal of the transmitting circuit of another one of the plurality of dies.

5. The memory device of claim 4, wherein the plurality of dies further comprises a plurality of second dies;
the plurality of second dies comprises a second die coupled with the transmitting circuit of the first die and a second die coupled with the receiving circuit of the first die; and
the receiving circuit of the second die receives a second selecting signal.

6. The memory device of claim 4, wherein the signal processing circuit of the first die is configured to generate a calibration enable signal based on a calibration command, the first selecting signal, and a first calibration flag signal; and
the first signal generating circuit of the first die is configured to generate the calibration start signal of the first die based on the calibration enable signal in response to the first selecting signal.

7. The memory device of claim 5, wherein the third enable signal comprises a first transition edge and a second transition edge, and the first transition edge is before the second transition edge;
the first signal generating circuit of the second die is configured to generate the calibration start signal of the second die based on the first transition edge of the third enable signal received by the receiving circuit of the second die in response to the second selecting signal; and
the second signal generating circuit of the first die is configured to generate the first calibration end signal of the first die based on the second transition edge of the third enable signal received by the receiving circuit of the first die in response to the first selecting signal.

8. The memory device of claim 4, wherein the first signal generating circuit comprises a first selecting circuit and a first signal generator; and the second signal generating circuit comprises a second selecting circuit and a second signal generator, wherein
a first input terminal of the first selecting circuit is coupled with the output terminal of the signal processing circuit, and a second input terminal of the first selecting circuit is coupled with the second output terminal of the transmitting circuit of the another one of the plurality of dies;
an input terminal of the first signal generator is coupled with an output terminal of the first selecting circuit, and an output terminal of the first signal generator is coupled with the calibration control circuit;
a first input terminal of the second selecting circuit is coupled with a first output terminal of the transmitting circuit, and a second input terminal of the second selecting circuit is coupled with the second output terminal of the transmitting circuit of the another one of the plurality of dies; and
an input terminal of the second signal generator is coupled with an output terminal of the second selecting circuit, and an output terminal of the second signal generator is coupled with the calibration control circuit.

9. The memory device of claim 8, wherein a control terminal of the first selecting circuit, and a control terminal of the second selecting circuit of the first die both receive the first selecting signal, wherein
the first selecting signal instructs the first selecting circuit to output a signal received by the first input terminal of the first selecting circuit; and
the first selecting signal instructs the second selecting circuit to output a signal received by the second input terminal of the second selecting circuit.

10. The memory device of claim 6, wherein the calibration command comprises a first calibration command and a second calibration command; the impedance calibration circuit further comprises a third selecting circuit, a first command generating circuit, and a second command generating circuit; an output terminal of the first command generating circuit is coupled with a first input terminal of the third selecting circuit; an output terminal of the second command generating circuit is coupled with a second input terminal of the third selecting circuit; and an output terminal of the third selecting circuit is coupled with an input terminal of the signal processing circuit, wherein
the first command generating circuit is configured to periodically generate the first calibration command;
the second command generating circuit is configured to receive and parse an external calibration command to generate the second calibration command; and
the third selecting circuit is configured to: in a first calibration mode, output the first calibration command; and in a second calibration mode, output the second calibration command.

11. The memory device of claim 1, wherein the receiving circuit comprises a flip-flop, wherein
a first input terminal of the flip-flop receives the calibration start signal;
a second input terminal of the flip-flop receives the first calibration end signal; and
the flip-flop is configured to output a second calibration flag signal based on the calibration start signal and the first calibration end signal.

12. The memory device of claim 1, wherein the impedance calibration circuit further comprises a calibration sub-circuit, wherein
the calibration sub-circuit is coupled with the calibration control circuit, and is coupled with a reference resistor; and
the calibration sub-circuit is configured to:
in response to the first enable signal, perform a first calibration operation based on the reference resistor and obtain a first calibration result; and
in response to the second enable signal, perform a second calibration operation based on the first calibration result and obtain a second calibration result.

13. The memory device of claim 12, further comprising an input/output circuit, wherein the input/output circuit comprises a pull-up driving circuit, a pull-down driving circuit, and the impedance calibration circuit of the first die; and
the calibration sub-circuit is further configured to transmit the first calibration result to one of the pull-up driving circuit and the pull-down driving circuit, and transmit the second calibration result to the other one of the pull-up driving circuit and the pull-down driving circuit.

14. A memory system, comprising:
at least one memory device, the memory device comprising:
a first die, comprising:
an impedance calibration circuit, comprising:
a receiving circuit,
a transmitting circuit, and
a calibration control circuit, wherein
the receiving circuit is coupled with the calibration control circuit and is configured to generate a calibration start signal;
the calibration control circuit is configured to generate a first enable signal based on the calibration start signal, and generate a second enable signal after generating the first enable signal;
the transmitting circuit is coupled with the calibration control circuit and is configured to output a third enable signal based on the second enable signal; and
the receiving circuit is further configured to generate a first calibration end signal; and
a controller coupled with the at least one memory device and configured to control the memory device.

15. The memory system of claim 14, wherein the controller is configured to generate an external calibration command; and
an input/output circuit in the memory device is configured to perform an impedance calibration operation in response to the external calibration command.

16. An operating method of an input/output circuit, comprising:
generating a calibration start signal;
generating a first enable signal based on the calibration start signal, and generating a second enable signal after generating the first enable signal;
outputting a third enable signal based on the second enable signal; and
generating a first calibration end signal.

17. The operating method of the input/output circuit of claim 16, further comprising:
generating a second calibration end signal based on the second enable signal.

18. The operating method of the input/output circuit of claim 16, wherein the generating the calibration start signal comprises:
generating a calibration enable signal based on a calibration command, a first selecting signal, and a first calibration flag signal; and
in response to the first selecting signal, generating the calibration start signal of the first die based on the calibration enable signal.

19. The operating method of the input/output circuit of claim 18, wherein the generating the calibration start signal further comprises:
in response to a second selecting signal, generating the calibration start signal of a second die based on a first transition edge of the third enable signal received by a receiving circuit of the second die; and
the generating the first calibration end signal comprises:
in response to the first selecting signal, generating the first calibration end signal based on a second transition edge of the third enable signal received by a receiving circuit of the first die.

20. The operating method of the input/output circuit of claim 18, wherein the calibration command comprises a first calibration command and a second calibration command; and
the operating method further comprises:
periodically generating the first calibration command;
receiving and parsing an external calibration command to generate the second calibration command;
in a first calibration mode, outputting the first calibration command; and
in a second calibration mode, outputting the second calibration command.
